(19) United States
(12) Patent Application Publication
(10) Pub. No.: US 2025/0095948 A1
(43) Pub. Date: Mar. 20, 2025

(54) ELECTRONIC COMPONENT AND CHARGED PARTICLE BEAM IRRADIATION APPARATUS

(71) Applicant: NuFlare Technology, Inc., Yokohama-shi (JP)

(72) Inventors: Yutaka ONOZUKA, Yokohama-shi (JP); Kazuyuki HIGASHI, Yokohama-shi (JP); Tomohiro SAITO, Yokohama-shi (JP); Yoshikuni GOSHIMA, White Plains, NY (US); Yoshiaki SHINOHARA, Hiratsuka-shi (JP)

(73) Assignee: NuFlare Technology, Inc., Yokohama-shi (JP)

(21) Appl. No.: 18/885,828

(22) Filed: Sep. 16, 2024

(30) Foreign Application Priority Data
Sep. 19, 2023 (JP) 2023-151759

(51) Int. Cl. H01J 37/04

(52) U.S. Cl. CPC H01J 37/045; H01J 2237/0435

(57) ABSTRACT

An electronic component of the embodiment includes: a first substrate including first through holes, a first substrate plane, and a second substrate plane; electrode pairs provided in the first through hole and including a first electrode a second electrode, an insulating film, at least a part of the insulating film being provided between an inner side surface of each of the first through holes and an outer side surface of the first electrode; wherein a surface of the insulating film exposed from the first and second electrode in the vicinity of the first and third end is located outside of a first and a third surface, the first surface is an inner side surface of the second portion, and the third surface is an inner side surface of the fifth portion.

### CROSS-REFERENCE TO RELATED APPLICATION

This application is based upon and claims the benefit of priority from Japanese Patent Applications No. 2023-151759, filed on Sep. 19, 2023, the entire contents of which are incorporated herein by reference.

### FIELD OF THE INVENTION

Embodiments described herein relate generally to an electronic component and a charged particle beam irradiation apparatus.

Along with the miniaturization of the Large Scale Integration (LSI), the photomask used in LSI fabrication processes is required to achieve both miniaturization of nm order and cost reduction. The photomask is manufactured by using an Electron Beam (EB) exposure device to draw a fine pattern on a glass substrate. In the conventional exposure device, a single electron beam system is used to scan a single electron beam. Therefore, it is difficult to achieve both miniaturization of pattern accuracy and high throughput. In order to solve this problem, a multi electron beam exposure device (the multi electron beam drawing apparatus) have been proposed which draws simultaneously with a plurality of electron beams.

In this multi electron beam exposure device, a blanking aperture array (BAA) having fine through holes and deflecting electrodes formed around the fine through holes are arranged. In addition, the blanking aperture array has a configuration in which electron beams can be irradiated in each of the through holes. The deflection electrode generates an electric field (deflection electric field) for deflecting the electron beam. Therefore, electron beams having arbitrary patterns can be generated by controlling on/off of the electron beams passing through each of the through holes according to a signal given to each pixel. By exposing the resist with the electron beams, the resist pattern having an arbitrary pattern can be formed.

For example, in the multi electron beam exposure device, the electron beams emitted from the electron gun is passed through the shaping aperture plate having a plurality of holes to form the multiple beams. The respective electron beams constituting the multiple beams are blanking-controlled by the blanking aperture array. The electron beam which is not deflected by the blanking aperture array is irradiated onto a target object such as a mask blank. On the other hand, the electron beam deflected by the blanking aperture array is shielded (blanked).

### SUMMARY OF THE INVENTION

An electronic component of the embodiment including: a first substrate including a plurality of first through holes, each of a plurality of charged particle beams passes through each of the plurality of first through holes, a first substrate plane, and a second substrate plane provided on the opposite side of the first substrate plane; a plurality of electrode pairs, each of the plurality of electrode pairs being provided in each of the plurality of first through holes, and each of the plurality of electrode pairs including a first electrode including a first portion, a second portion connected to the first portion, and the second portion including a first end, and a third portion connected to the first portion, and the third portion including a second end, and a second electrode spaced apart from the first electrode, the second electrode facing the first electrode, and the second electrode including a fourth portion facing the first portion, a fifth portion connected to the fourth portion, the fifth portion including a third end, and the third end facing the first end, and a sixth portion connected to the fourth portion, the sixth portion including a fourth end, and the fourth end facing the second end; an insulating film, at least a part of the insulating film being provided between an inner side surface of each of the first through holes and an outer side surface of the first electrode and between the inner side surface of each of the first through holes and an outer side surface of the second electrode; wherein a surface of the insulating film exposed from the first electrode and the second electrode in the vicinity of the first end and the third end is located outside of a first surface and a third surface, the first surface is an inner side surface of the second portion, and the third surface is an inner side surface of the fifth portion, and wherein the surface of the insulating film exposed from the first electrode and the second electrode in the vicinity of the second end and the fourth end is located outside of a fifth surface and a seventh surface, the fifth surface is an inner side surface of the third portion, and the seventh surface is an inner side surface of the sixth portion.

### BRIEF DESCRIPTION OF THE DRAWINGS

FIG. 1 is a schematic cross-sectional view of an electron beam drawing apparatus of a first embodiment.

FIGS. 2A-B are schematic cross-sectional views of the main part of an electronic component of the first embodiment.

FIG. 3 is a schematic cross-sectional view of the main part of the electronic component of the first embodiment.

FIG. 4 is a schematic cross-sectional view of the main part of the electronic component in the first other aspect of the electronic component of the first embodiment.

FIG. 5 is a schematic cross-sectional view of the main part of the electronic component in the second other aspect of the electronic component of the first embodiment.

FIGS. 6A-B are schematic cross-sectional views showing a process for manufacturing the electronic component of the first embodiment.

FIGS. 7A-B are schematic cross-sectional views showing the process for manufacturing the electronic component of the first embodiment.

FIGS. 8A-B are schematic cross-sectional views showing the process for manufacturing the electronic component of the first embodiment.

FIGS. 9A-B are schematic cross-sectional views showing the process for manufacturing the electronic component of the first embodiment.

FIG. 10 is a schematic cross-sectional view of the main part of the electronic component of the comparative embodiment of the first embodiment.

FIG. 11 is a schematic cross-sectional view of the main part of the electronic component of the second embodiment.

FIG. 12 is a schematic cross-sectional view of the main part of the electronic component of the third embodiment.

FIG. 13 is a schematic cross-sectional view of the main part of the electronic component of the fourth embodiment.

FIG. 14 is a schematic cross-sectional view of the main part of the electronic component of the fifth embodiment.

FIG. 15 is a schematic cross-sectional view of the main part of the electronic component of the sixth embodiment.

FIG. 16 is a schematic cross-sectional view of the main part of the electronic component of the seventh embodiment.

FIGS. 17A-F show electric potential distribution of the electronic component of the embodiment.

FIGS. 18A-B are graphs of the electric field of the electronic component of the embodiment.

### DETAILED DESCRIPTION OF THE EMBODIMENTS

Hereinafter, embodiments will be described with reference to the drawings. In the drawings, the same or similar parts are denoted by the same or similar reference numerals.

In the present specification, the same or similar members are denoted by the same reference numerals, and redundant description thereof may be omitted.

In the present specification, in order to show the positional relationship of the components and the like, the upward direction of the drawings is described as “up”, and the downward direction of the drawings is described as “down”. In the present specification, the terms “upper” and “lower” do not necessarily indicate the relationship with the direction of gravity.

Hereinafter, a structure using the electron beam will be described as an exemplary the charged particle beam. However, the charged particle beam is not limited to an electron beam. The charged particle beam can be the ion beam.

### First Embodiment

An electronic component of the present embodiment including: a first substrate including a plurality of first through holes, each of a plurality of charged particle beams passes through each of the plurality of first through holes, a first substrate plane, and a second substrate plane provided on the opposite side of the first substrate plane; a plurality of electrode pairs, each of the plurality of electrode pairs being provided in each of the plurality of first through holes, and each of the plurality of electrode pairs including a first electrode including a first portion, a second portion connected to the first portion, and the second portion including a first end, and a third portion connected to the first portion, and the third portion including a second end, and a second electrode spaced apart from the first electrode, the second electrode facing the first electrode, and the second electrode including a fourth portion facing the first portion, a fifth portion connected to the fourth portion, the fifth portion including a third end, and the third end facing the first end, and a sixth portion connected to the fourth portion, the sixth portion including a fourth end, and the fourth end facing the second end; an insulating film, at least a part of the insulating film being provided between an inner side surface of each of the first through holes and an outer side surface of the first electrode and between the inner side surface of each of the first through holes and an outer side surface of the second electrode; wherein a surface of the insulating film exposed from the first electrode and the second electrode in the vicinity of the first end and the third end is located outside of a first surface and a third surface, the first surface is an inner side surface of the second portion, and the third surface is an inner side surface of the fifth portion, and wherein the surface of the insulating film exposed from the first electrode and the second electrode in the vicinity of the second end and the fourth end is located outside of a fifth surface and a seventh surface, the fifth surface is an inner side surface of the third portion, and the seventh surface is an inner side surface of the sixth portion.

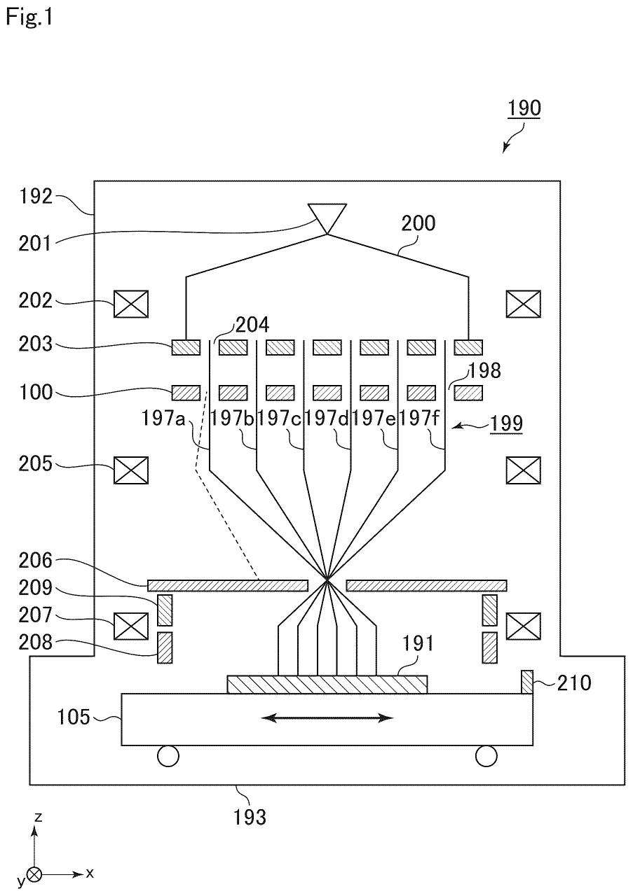

FIG. 1 is the schematic cross-sectional view of the electron beam drawing apparatus 190 of the first embodiment.

The electronic component 100 of the present embodiment is used, for example, as the blanking aperture array (the deflector) of the electron beam drawing apparatus 190. Note that the use of the electronic component 100 is not limited to this.

The electron beam drawing apparatus 190 includes the electron optical column 192 (multi electron beam column) and the drawing chamber 193. Disposed within the electron optical column 192 are the electron gun 201, the illumination lens 202, the shaping aperture array 203, the electronic component 100, the reduction lens 205, the limiting aperture plate member 206, the objective lens 207, the main deflector 208, and the secondary deflector 209.

The electron gun 201 emits the electron beam 200. The electron gun 201 is an exemplary the irradiation source.

Here, the X direction, the Y direction intersecting perpendicularly with the X direction, and the Z direction intersecting perpendicularly with the X direction and the Y direction are defined. It is assumed that the electron gun 201 emits an electron beam 200 oppositely to the Z direction. Further, it is assumed that the target object 191 is disposed to be parallel to the XY plane.

The electron beam 200 emitted from the electron gun 201 illuminates the shaping aperture array 203 substantially perpendicularly by the illumination lens 202. The multiple beams 199 are formed by passing the electron beam 200 through the openings of the shaping aperture array 203. The multiple beams 199 have the electron beam 197a, 197b, 197c, 197d, 197e and 197f. The shape of each of the electron beams 197 reflects the shape of the opening of the shaping aperture array 203. Each electron beam 197 has, for example, a rectangular shape. Here, the number of the openings 204 of the shaping aperture array 203 illustrated in FIG. 1 is six. However, the number of the openings 204 of the shaping aperture array 203 is not limited to six. The number of the multiple beams 199 formed by the shaping aperture array 203, illustrated in FIG. 1, is six. However, the number of the multiple beams 109 formed by the shaping aperture array 203 is not limited to six.

The electronic component 100 is provided below the shaping aperture array 203. The position of the electron beam 197 deflected by the electronic component 100 deviates from the central bore of the limiting the aperture plate member 206. The electron beam 197 deflected by the electronic component 100 is shielded by the limiting aperture plate member 206. On the other hand, the electron beam 197 that has not been deflected by the electronic component 100 passes through the central bore of the limiting aperture plate member 206. In this way, the on/off of the electron beam is controlled. Here, the number of the openings 198 of the electronic component 100 illustrated in FIG. 1 is six. However, the number of the openings 198 of the electronic component 100 is not limited to six.

The focus of the electron beam 197 passing through the aperture plate member 206 is appropriately adjusted by the objective lens 207. After that, the electron beam 197 that has passed through the limiting the aperture plate member 206 becomes a patterned image having a desired reduction ratio. Thereafter, the electron beam 197 that has passed through the limiting aperture plate member 206 is collectively deflected by the main deflector 208 and the secondary deflector 209. Thereafter, the electron beam 197 that has passed through the limiting the aperture plate member 206 is irradiated to the respective irradiation position on the target object 101 placed on the XY stage 105. On the XY stage 105, a mirror 210 for measuring the position of the XY stage 105 is disposed.

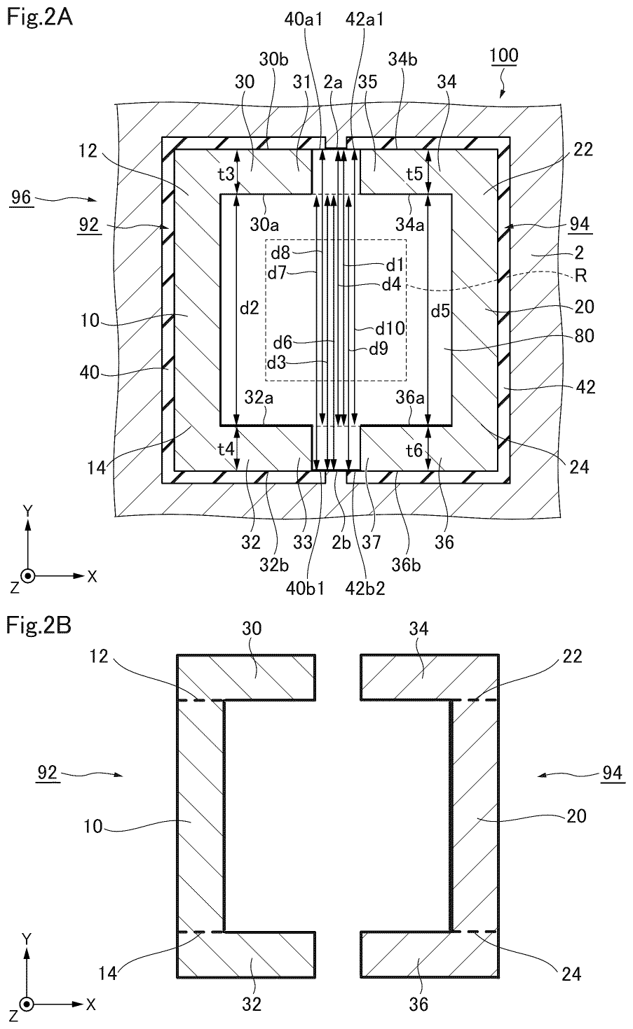

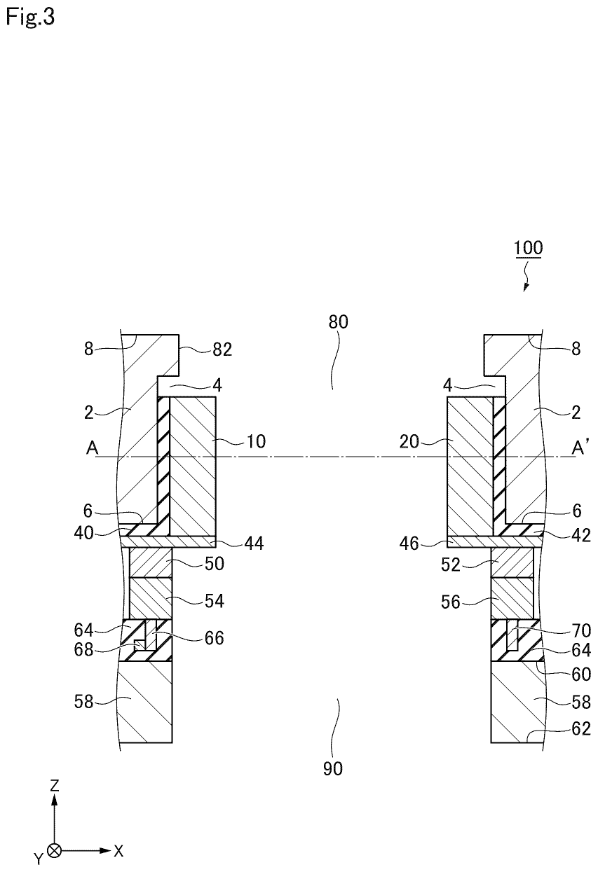

FIGS. 2A-B are schematic cross-sectional views of the main part of the electronic component of the first embodiment. The electronic component 100 is structure A1_2u. FIG. 3 is the schematic cross-sectional view in the XZ plane of the electronic component 100 of the present embodiment. FIG. 2A is the schematic cross-sectional view of the main part of the electronic component 100 of the present embodiment in A-A′ cross-section indicated by FIG. 3. FIG. 2B is the schematic diagram showing examples of the first portion 10, the second portion 30, the third portion 32, the first connection portion 12, the second connection portion 14, the fourth portion 20, the fifth portion 34, the sixth portion 36, the third connection portion 22, and the fourth connection portion 24.

The electronic component 100 of the present embodiment will be described using FIGS. 2A-B and FIG. 3.

The first substrate 2 is, for example, a semiconductor substrate. The first substrate 2 is, for example, a Si (silicone) substrate. However, the first substrate 2 is not limited to the semiconductor substrate. For example, as the first substrate 2, other substrate such as an insulating substrate can be preferably used. Here, the insulating substrate is, for example, a ceramic substrate. The insulating substrate is, for example, a glass epoxy substrate containing glass fibers and an epoxy resin.

The first substrate 2 has the first substrate plane 6 and the second substrate plane 8 provided on the opposite side of the first substrate plane 6. In FIG. 3, the first substrate plane 6 is shown to be provided below the second substrate plane 8. The first substrate plane 6 and the second substrate plane 8 are provided to be parallel to XY plane.

The first substrate 2 has a plurality of first through holes 80. Each of the electron beams 197 included in the multiple beams 199 passes through each of the plurality of first through holes 80. In FIG. 2A, the electron beam passing area R through which the electron beam 197 passes is also shown.

In the electronic component 100 shown in FIGS. 2A-B, the shapes of the plurality of first through holes 80 in the plane parallel to the XY plane are squares. However, the shapes of the plurality of first through holes 80 in the plane parallel to the XY plane are not limited to squares.

The plurality of first electrodes 92 are respectively provided in the plurality of first through holes 80. The first electrode 92 includes the first portion 10, the second portion 30, and the third portion 32.

The plurality of second electrodes 94 are respectively provided in the plurality of first through holes 80. The second electrode 94 includes the fourth portion 20, the fifth portion 34, and the sixth portion 36.

The plurality of electrode pairs 96 are respectively provided in the plurality of first through holes 80. The electrode pair 96 includes, in the first through hole 80, the first electrode 92 and the second electrode 94 spaced apart from and opposed to the first electrode 92.

The plurality of first portions 10 are respectively provided in the plurality of first through holes 80. The first portion 10 includes the first connection portion 12 and the second connection portion 14. The first portion 10 extends in the Y direction. The first portion 10 is provided to be parallel to the Y direction. The shapes of the plurality of first portions 10 when viewed from above are, for example, rectangular shapes. Note that the Y direction is an exemplary the first direction. As shown in FIG. 2B, the first connection portion 12 and the second connection portion 14 are, for example, surfaces of the first portion 10 that are parallel to the XZ plane.

The plurality of fourth portions 20 are respectively provided in the plurality of first through holes 80. The plurality of fourth portions 20 respectively face the plurality of first portions 10. The fourth portion 20 has the third connection portion 22 facing the first connection portion 12 and the fourth connection portion 24 facing the second connection portion 14. Each of the plurality of fourth portions 20 extends in the Y direction. Each of the plurality of fourth portions 20 is provided to be parallel to the Y direction. The shapes of the plurality of fourth portions 20 when viewed from above are, for example, rectangular shapes. As shown in FIG. 2B, the third connection portion 22 and the fourth connection portion 24 are, for example, surfaces of the fourth portion 20 that are parallel to the XZ plane.

The plurality of second portions 30 are respectively provided in the plurality of first through holes 80. The second portion 30 is connected to the first connection portion 12. The second portion 30 has the first end 31 extending towards the third connection portion 22. The second portion 30 extends in the X direction. Each of the plurality of second portions 30 is provided to be parallel to the X direction. The shapes of the plurality of second portions 30 when viewed from above are, for example, rectangular shapes. Note that the X direction is an exemplary the second direction.

The plurality of third portions 32 are respectively provided in the plurality of first through holes 80. The third portion 32 is connected to the second connection portion 14. The third portion 32 has the second end 33 extending towards the fourth connection portion 24. The third portion 32 extends in the X direction. Each of the plurality of third portions 32 is provided to be parallel to the X direction. The shapes of the plurality of third portions 32 when viewed from above are, for example, rectangular shapes.

The plurality of fifth portions 34 are respectively provided in the plurality of first through holes 80. The fifth portion 34 is connected to the third connection portion 22. The fifth portion 34 has the third end 35 extending towards the first connection portion 12 or the first end 31 and provided to be spaced apart from the first end 31. The fifth portion 34 extends in the −X direction. The fifth portion 34 is provided to be parallel to the X direction. The shapes of the plurality of fifth portions 34 when viewed from above are, for example, rectangular shapes.

The plurality of sixth portions 36 are respectively provided in the plurality of first through holes 80. The sixth portion 36 is connected to the fourth connection portion 24. The sixth portion 36 has the fourth end 37 extending towards the second connection portion 14 or the second end 33 and provided to be spaced apart from the second end 33. The sixth portion 36 extends in the −X direction. The sixth portion 36 is provided to be parallel to the X direction. The shapes of the plurality of sixth portions 36 when viewed from above are, for example, rectangular shapes.

As described above, the third end 35 is provided to be spaced apart from the first end 31 and to face the first end 31. Therefore, in the vicinity of the first end 31 and the third end 35, the first side surface 2a of the first through hole 80 is exposed.

As described above, the fourth end 37 is provided to be spaced apart from the second end 33 and to face the second end 33. Therefore, in the vicinity of the second end 33 and the fourth end 37, the second side surface 2b of the first through hole 80 is exposed.

The plurality of first insulating films 40 is provided in each of the plurality of first through holes 80 between the outer side surface of the first electrode 92 and the inner side surface of the first through hole 80. In other words, the plurality of first insulating films 40 are provided between the first substrate 2 and the first portion 10, the second portion 30 and the third portion 32 in each of the plurality of first through holes 80. Further, the first insulating film 40 is provided in contact with the first substrate plane 6. The seventh distance d7 between the second portion 30 and the first insulating film 40 in the vicinity of the second end 33 in the Y direction is longer than the second distance d2 between the second portion 30 and the third portion 32 in the Y direction. The eighth distance d8 between the third portion 32 and the first insulating film 40 in the vicinity of the first end 31 in the Y direction is longer than the second distance d2 in the Y direction. Further, the seventh distance d7 is preferably equal to or longer than the sum of the second distance d2 and the film thickness t4 of the third portion 32 in the Y direction (d7≥d2+t4). Further, the eighth distance d8 is preferably equal to or longer than the sum of the second distance d2 and the film thickness t3 of the second portion 30 in the Y direction (d8≥d2+t3). The plurality of first insulating films 40 includes, for example, SiOx (silicon oxide).

In the vicinity of the first end 31, the side surface 40a1 of the first insulating film 40 is exposed. Also, in the vicinity of the second end 33, the side surface 40b1 of the first insulating film 40 is exposed.

The plurality of second insulating films 42 is provided in each of the plurality of first through holes 80 between the outer side surface of the second electrode 94 and the inner side surface of the first through hole 80 and is provided to be spaced apart from the first insulating film 40. In other words, the plurality of second insulating films 42 is provided between the first substrate 2 and the fourth portion 20, the fifth portion 34 and the sixth portion 36 in each of the plurality of first through holes 80. The plurality of second insulating films 42 is provided to be spaced apart from the plurality of first insulating films 40 in each of the plurality of first through holes 80. Further, the second insulating film 42 is provided in contact with the first substrate plane 6. The ninth distance d9 between the fifth portion 34 and the second insulating film 42 in the vicinity of the fourth end 37 in the Y direction is longer than the fifth distance d5 between the fifth portion 34 and the sixth portion 36 in the Y direction. The tenth distance d10 between the sixth portion 36 and the second insulating film 42 in the vicinity of the third end 35 in the Y direction is longer than the fifth distance d5 in the Y direction. Further, the ninth distance d9 is preferably equal to or longer than the sum of the fifth distance d5 and the thickness t6 of the sixth portion 36 in the Y direction (d9≥d5+t6). Further, the tenth distance d10 is preferably equal to or longer than the sum of the fifth distance d5 and the thickness t5 of the fifth portion 34 in the Y direction (d10≥d5+t5). The plurality of second insulating films 42 includes, for example, SiOx (silicon oxide).

The side surface 42a1 of the second insulating film 42 is exposed in the vicinity of the third end 35. The side surface 42b2 of the second insulating film 42 is exposed in the vicinity of the fourth end 37.

However, the shapes of the plurality of first insulating films 40 and the shapes of the plurality of second insulating films 42 are not limited to those described above.

The first distance d1 between the third portion 32 and the first side surface 2a of the first through hole 80 exposed in the vicinity of the first end 31 and the third end 35 in the Y direction is equal to or longer than the second distance d2 between the second portion 30 and the third portion 32 in the Y direction.

The third distance d3 between the second portion 30 and the second side surface 2b of the first through hole 80 exposed in the vicinity of the second end 33 and the fourth end 37 in the Y direction is equal to or longer than the second distance d2 between the second portion 30 and the third portion 32 in the Y direction.

The fourth distance d4 between the sixth portion 36 and the first side surface 2a of the first through hole 80 exposed in the vicinity of the first end 31 and the third end 35 in the Y direction is equal to or longer than the fifth distance d5 between the fifth portion 34 and the sixth portion 36 in the Y direction.

The sixth distance d6 between the fifth portion 34 and the second side surface 2b of the first through hole 80 exposed in the vicinity of the second end 33 and the fourth end 37 in the Y direction is equal to or longer than the fourth distance d4 between the fifth portion 34 and the sixth portion 36 in the Y direction.

In other words, the first side surface 2a of the first through hole 80 exposed in the vicinity of the first end 31 and the third end 35 is located outside of the first surface 30a and the third surface 34a. The first surface 30a is the inner side surface of the second portion 30. The third surface 34a is the inner side surface of the fifth portion 34. In other words, the second side surface 2b of the first through hole 80 exposed in the vicinity of the second end 33 and the fourth end 37 is located outside of the fifth surface 32a and the seventh surface 36a. The fifth surface 32a is the inner side surface of the third portion 32. The seventh surface 36a is the inner side surface of the sixth portion 36.

In FIG. 2A, it is illustrated as d1=d4, d2=d5 and d3=d6.

The circuit board (exemplary the second substrate) 58 has the third substrate surface 60 and the fourth substrate surface 62. The third substrate surface 60 is provided to face the first substrate plane 6. The circuit board 58 is, for example, a silicon substrate. However, the circuit board 58 is not limited to the silicon substrate. The circuit board 58 has the plurality of second through holes 90.

The pair of the first through hole 80 and the second through hole 90 corresponds to the opening 198 (FIG. 1). Each of the first through holes 80 is provided above each of the second through holes 90, respectively.

In FIGS. 2A-B and FIG. 3, one first through hole 80 among the plurality of first through holes 80 included in the first substrate 2 is illustrated. In FIGS. 2A-B and FIG. 3, one second through hole 90 among the plurality of second through holes 90 included in the circuit board 58 is illustrated.

The insulating film 64 is provided on the third substrate surface 60 of the circuit board 58. The insulating film 64 includes, for example, silicon oxide. However, the insulating film 64 may be, for example, a stacked film of a film containing silicon oxide and a film containing SiNx (silicon nitride).

Each of the plurality of first plate electrodes 44 is provided below the first portion 10 and below the first insulating film 40 in contact with the first portion 10. Each of the plurality of first plate electrodes 44 is electrically connected to the first portion 10.

Each of the plurality of first junction electrodes 50 is provided below each of the plurality of first plate electrodes 44. Each of the plurality of first junction electrodes 50 is electrically connected to each of the plurality of first plate electrodes 44. Each of the plurality of first junction electrodes 50 is provided on the first substrate plane 6 via the first insulating film 40.

Each of the plurality of second plate electrodes 46 is provided below the fourth portion 20 and below the second insulating film 42 in contact with the fourth portion 20. Each of the plurality of second plate electrodes 46 is electrically connected to the fourth portion 20.

Each of the plurality of second junction electrodes 52 is provided below each of the second plate electrodes 46. Each of the plurality of second junction electrodes 52 is electrically connected to each of the plurality of second plate electrodes 46. Each of the plurality of second junction electrodes 52 is provided on the first substrate plane 6 via the second insulating film 42.

Each of the plurality of third junction electrodes 54 is provided below each of the plurality of first junction electrodes 50. Each of the plurality of third junction electrodes 54 is electrically connected to each of the plurality of first junction electrodes 50. Each of the plurality of third junction electrodes 54 is provided on the third substrate surface 60 via the insulating film 64.

Each of the plurality of fourth junction electrodes 56 is provided below each of the plurality of second junction electrodes 52. Each of the plurality of fourth junction electrodes 56 is electrically connected to each of the plurality of second junction electrodes 52. Each of the plurality of fourth junction electrodes 56 is provided on the third substrate surface 60 via the insulating film 64.

The length of the plurality of first junction electrodes 50 in the Z direction, the length of the plurality of second junction electrodes 52 in the Z direction, the length of the plurality of third junction electrodes 54 in the Z direction, and the length of the plurality of fourth junction electrode 56 in the Z direction are, for example, about 2 μm.

In the vicinity of the second substrate plane 8, the side surfaces of the plurality of first through holes 80 may have the exposed portions (parts where parts of the first substrate 2 are exposed) 82. Note that the side surfaces of the plurality of first through holes 80 may not have the exposed portions 82.

The first substrate 2 has a plurality of concavities 4. Each the concavities 4 is provided on the side surface of the first through hole 80 between the first insulating film 40 and the second substrate plane 8 so as to surround the first through hole 80. In the vicinity of the second substrate plane 8, when the side surfaces of the plurality of first through holes 80 may have the exposed portions 82, the concavity 4 is provided on the side surface of the first through hole 80 between the first insulating film 40 and the exposed portion 82 so as to surround the first through hole 80. Note that the plurality of concavities 4 may not be provided.

The plurality of control circuits 68 are provided in the insulating film 64 below the first portion 10. The control circuit 68 is, for example, a CMOS (Complimentary Metal-Oxide-Semiconductor) circuitry. The control circuit 68 has a function of applying a predetermined voltage of, for example, a 5V degree to each of the plurality of the first portion 10 via the wiring 66 provided in the insulating film 64, the third junction electrode 54, the first junction electrode 50, and the first plate electrode 44.

The wiring 70 is provided in the insulating film 64. The wiring 70 is connected to the fourth junction electrode 56. The wiring 70 grounds the fourth portion 20 via the second plate electrode 46, the second junction electrode 52, and the fourth junction electrode 56.

Note that the first substrate 2 and the circuit board 58 may be grounded.

The plurality of first portions 10, the plurality of fourth portions 20, the plurality of second portions 30, the plurality of third portions 32, the plurality of fifth portions 34, and the plurality of sixth portions 36 include, for example, metal nitrides such as TiN (titanium nitride), or metals such as W (tungsten).

The plurality of first plate electrodes 44, the plurality of second plate electrodes 46, the plurality of first junction electrodes 50, the plurality of second junction electrodes 52, the plurality of third junction electrodes 54, the plurality of fourth junction electrodes 56, the wirings 66, and the wirings 70 include, for example, metals such as Au (gold), and TiN (titanium nitride).

Note that a barrier metal (not shown) may be provided between the first insulating film 40 and the first portion 10, the second portion 30, and the third portion 32. A barrier metal (not shown) may be provided between the second insulating film 42 and the fourth portion 20, the fifth portion 34, and the sixth portion 36. The barrier metal includes, for example, TiN.

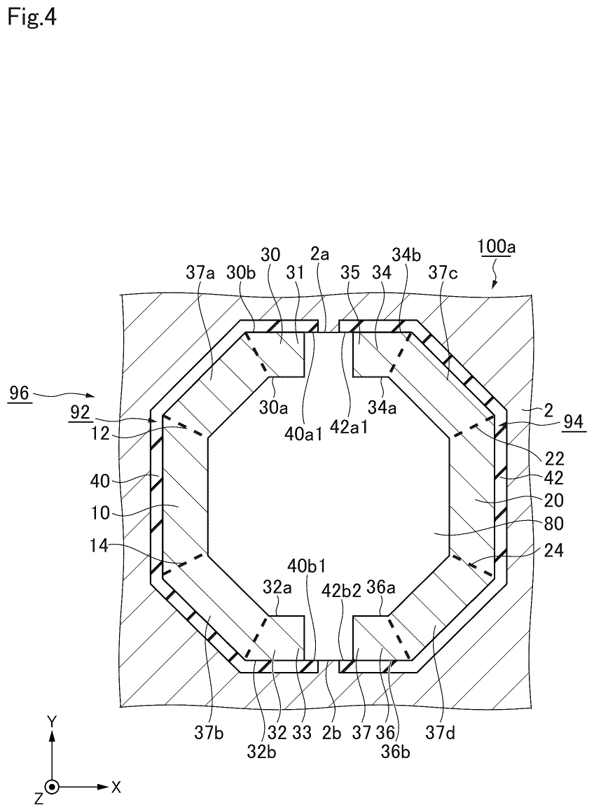

FIG. 4 is the schematic cross-sectional view of the main part of the electronic component 100a in the other aspect of the electronic component of the first embodiment. The shape of the first through hole 80 when viewed from above may be, for example, an octagonal shape.

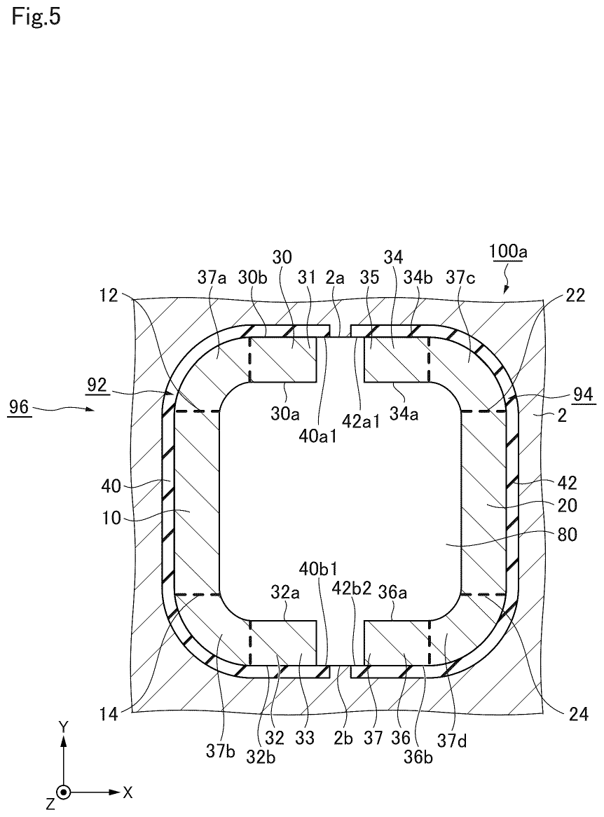

FIG. 5 is the schematic cross-sectional view of the main part of the electronic component in the other aspect of the electronic component of the first embodiment. The shape of the first through hole 80 when viewed from above may be, for example, a rectangular shape with chamfered corners (R-chamfered).

In addition, in the electronic component 100a and the electronic component 100b, the first connection electrode 37a connecting the first connection portion 12 and the second portion 30, the second connection electrode 37b connecting the second connection portion 14 and the third portion 32, the third connection electrode 37c connecting the third connection portion 22 and the fifth portion 34, and the fourth connection electrode 37d connecting the fourth connection portion 24 and the sixth portion 36 may be provided. In this case, the first insulating film 40 is provided between the first substrate 2 and the first portion 10, the second portion 30, the third portion 32, the first connection electrode 37a and the second connection electrode 37b. The second insulating film 42 is provided between the first substrate 2 and the fourth portion 20, the fifth portion 34, the sixth portion 36, the third connection electrode 37c, and the fourth connection electrode 37d.

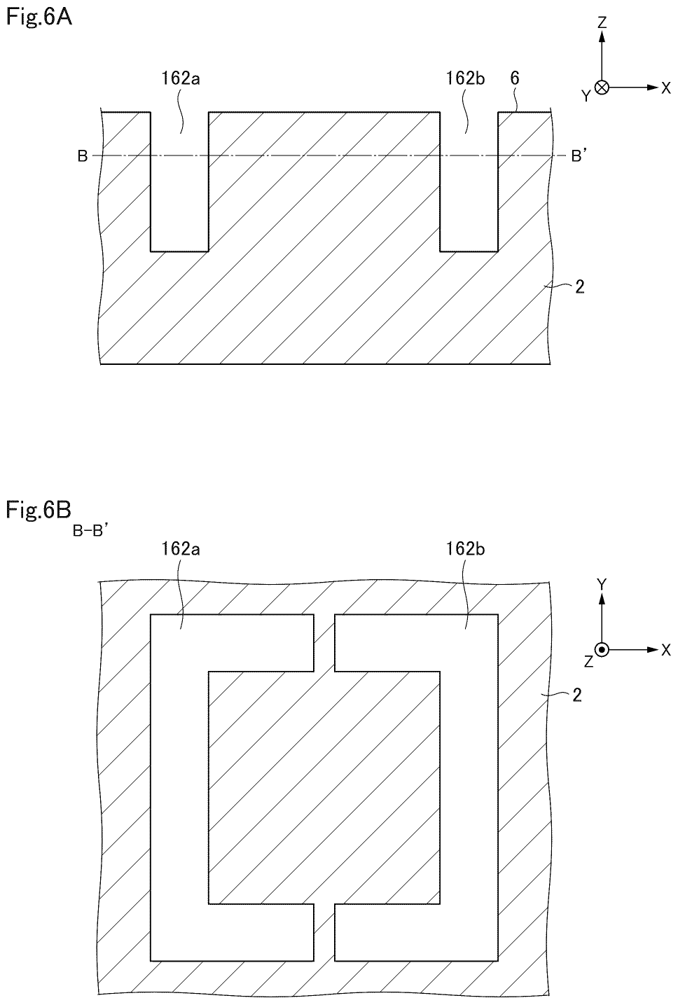

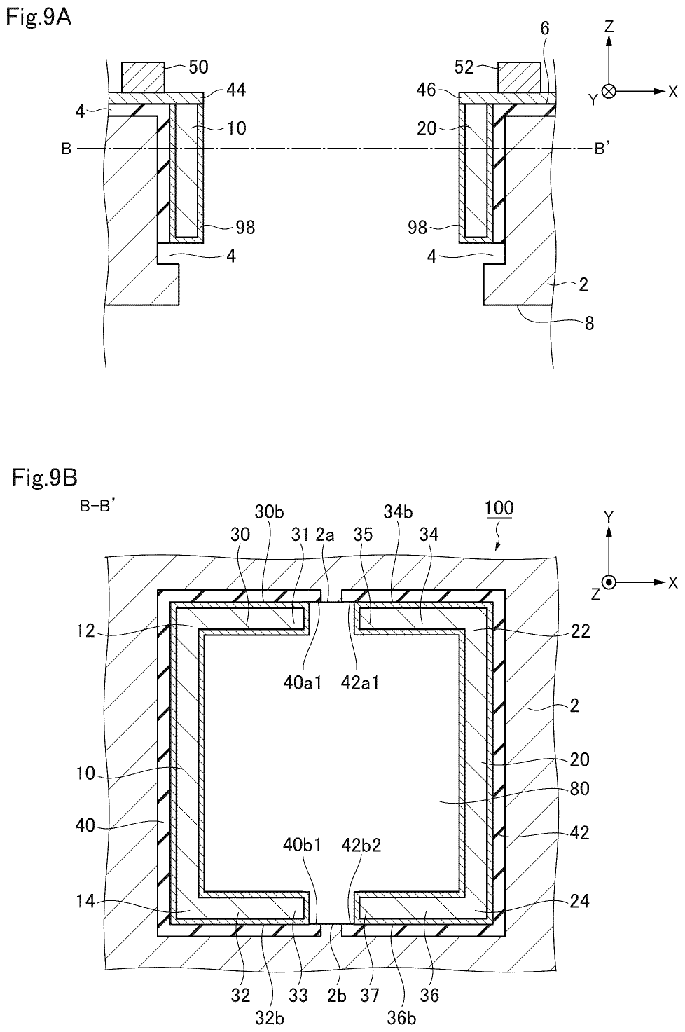

FIGS. 6A-B to FIGS. 9A-B are schematic cross-sectional views showing a process for manufacturing the electronic component 100 of the present embodiment.

First, a U-shaped groove 162 is formed on the first substrate plane 6 of the first substrate 2 by, for example, a photolithography method and RIE (Reactive Ion Etching method. The width of the groove 162 is, for example, 2 μm or more and 6 μm or less. The depth of the groove 162 is, for example, about 60 μm (FIGS. 6A-B). In FIG. 4, a groove 162a and a groove 162b are illustrated.

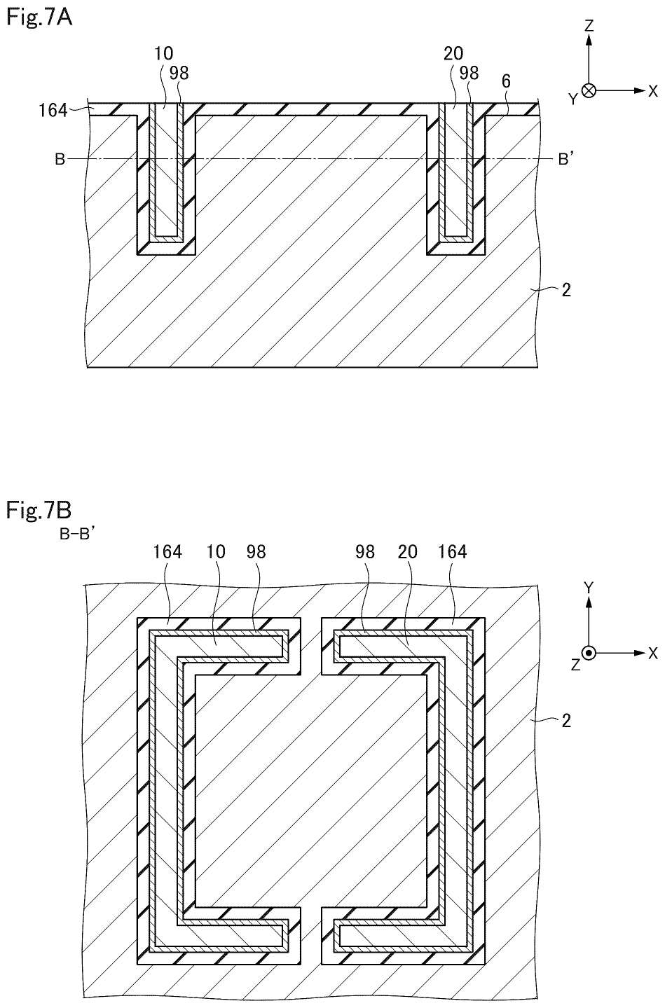

Next, the insulating film 164 containing, for example, silicon oxide is formed on the inside of the groove 162a, the inside of the groove 162b, and the first substrate plane 6 by, for example, CVD (Chemical Vapor Deposition) method using Tetraethyl orthosilicate (TEOS) as a raw material gas. Next, the barrier metal 98 including a metal nitride such as TiN (titanium nitride) is formed on the insulating film 164 formed in the trench 162a and the trench 162b, for example, by sputtering. Next, the first portion 10 and the fourth portion 20 including a metal nitride such as TiN (titanium nitride) or a metal such as W (tungsten) are formed on the barrier metal 98 by, for example, CVD method. Thereafter, the upper surfaces of the insulating film 164, the barrier metal 98, the first portion 10, and the fourth portion 20 are planarized by, for example, etch back (FIGS. 7A-B).

Next, the first plate electrode 44 including, for example, a TiN is formed over the first portion 10 and over the insulating film 104 on the upper left of the first portion 10. The second plate electrode 46 including, for example, a TiN is formed over the fourth portion 20 and over the insulating film 104 on the upper right of the fourth portion 20. Note that when forming the first plate electrode 44 and the second plate electrode 46, for example, a plating method and a photolithography method are used.

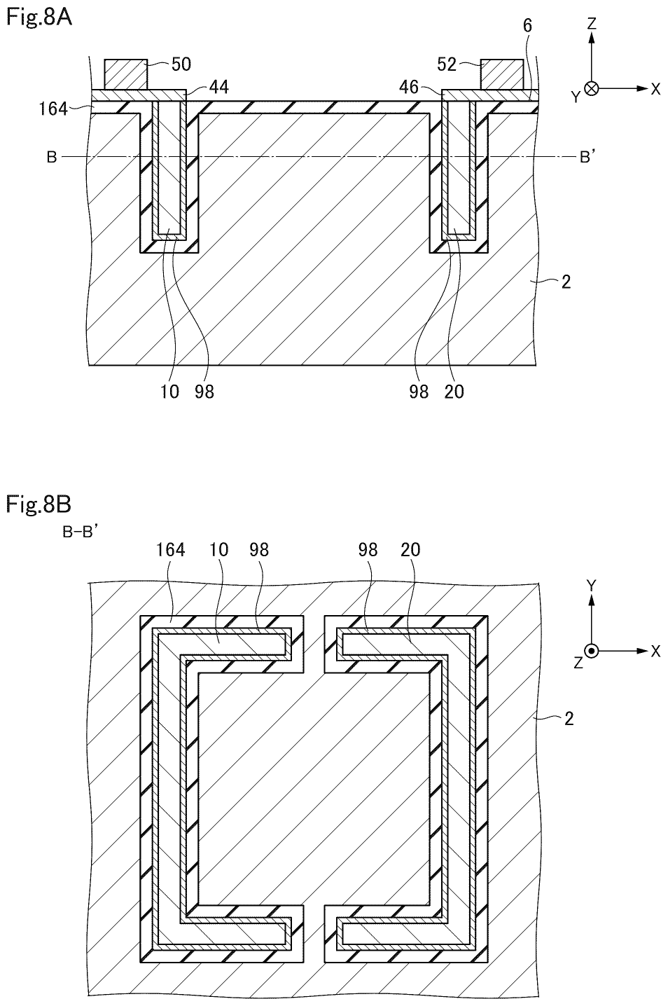

Next, the first junction electrode 50 including, for example, gold (Au) is formed on the first plate electrode 44. The second junction electrode 52 including, for example, gold is formed on the second plate electrode 46. Note that when forming the first junction electrode 50 and the second junction electrode 52, for example, a plating method and a photolithography method are used (FIGS. 8A-B).

Next, for example, the surface of the first substrate 2 facing the first substrate plane 6 is polished. Thus, the first substrate 2 is thinned. The second substrate plane 8 is formed on the surface of the first substrate 2 facing the first substrate plane 6.

The first substrate 2 between the first portion 10 and the fourth portion 20 is then removed, e.g., by RIE, to form the first through hole 80. The first side surface 2a and the second side surface 2b are formed on the side surface of the first through hole 80. Next, the insulating film 164 provided on the right side and the bottom of the first portion 10 and the insulating film 164 provided on the left side and the bottom of the fourth portion 20 are removed by, for example, Vapor HF (hydrofluoric acid in vapor form). By removing the insulating film 164, the first insulating film 40 and the second insulating film 42 are formed. The first insulating film 40 is removed isotropically by the Vapor HF. Therefore, the concavity 4 surrounding the first through hole 80 is formed on the side surface of the first through hole 80 below the first insulating film 40 (FIGS. 9A-B).

The third junction electrode 54 of the circuit board 58 having the second through hole 90, the insulating film 64, the wiring 66, the control circuit 68, the wiring 70, the third junction electrode 54 and the fourth junction electrode 56 is bonded to the first junction electrode 50. The fourth junction electrode 56 is bonded to the second junction electrode 52. As a result, the electronic component 100 of the present embodiment is obtained.

Next, the effects of the electronic component 100 of the present embodiment will be described.

The size of the electrode provided in the vicinity of the first through hole 80 is preferably longer in terms of the electron passing direction (the direction parallel to the Z direction) from the viewpoint of improving the electron deflection. On the other hand, when the electronic component is used as the blanking aperture array, it is preferable that the size of the electrode be smaller in a plane parallel to XY plane from the viewpoint of improving the definition of the blanking aperture array. Namely, it is preferable that the shape of the first through hole 80 have a high aspect ratio. The aspect ratio is obtained by dividing the length in the direction parallel to the Z direction by the length in the direction parallel to the X direction or the Y direction. It is preferable that the length of the electrode in the Z direction (the height of the electrode) is, for example, 25 μm or more and 30 μm or less when the length of the electrode in the X direction is 4 μm and the length of the electrode in the Y-direction is 6 μm and when the spacing (array pitch) between the first through hole 80 in the X direction and the Y direction is 24 μm.

However, it is difficult to form such an electrode with a fine pitch. For example, this electrode can be formed by forming thick film resist patterns, forming metal films between the resist patterns using an electroplating method, and then peeling the resist patterns. However, in order to form such an electrode with a fine pitch, it is required to form a thick resist pattern with an aspect and a pitch of substantially the same level. However, it is difficult to form such a thick resist pattern. In addition, when an electrode is deposited between the resist patterns by an electroplating method, there is a problem that in-plane film thickness unevenness is large.

Therefore, it is conceivable to bond the circuit board 58 having the control circuit 68, the second through holes 90, and the metal bumps (the third junction electrodes 54 and the fourth junction electrodes 56) to the first substrate 2 having the first through hole 80 by heat-crimping the metal bumps. Thus, an electrode having a high aspect ratio can be obtained.

However, there may be a surface on which the insulating film is exposed inside the first through hole 80. When the surface of the insulating film is charged, the electric field generated by the charging is deflected in a direction different from the intended direction. Examples of such insulating film include a native oxide film formed on the side surface of the first insulating film 40, on the side surface of the second insulating film 42, or on the exposed Si surface. Any insulating film may be formed on the walls of the first through hole 80.

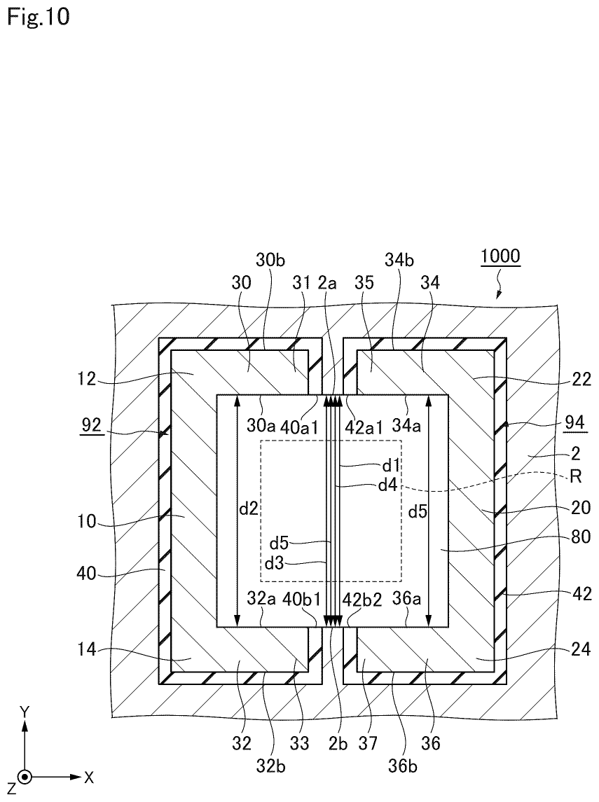

FIG. 10 is the schematic cross-sectional view of the main part of the electronic component 1000 of the comparative embodiment of the first embodiment. The electronic component 1000 is structure A0. In the electronic component 1000, the first insulating film 40 is provided between the first end 31 and the third end 35 and between the second end 33 and the fourth end 37. The second insulating film 42 is provided between the first end 31 and the third end 35 and between the second end 33 and the fourth end 37. In such cases, an electric field is likely to be applied to the inside of the first through hole 80. Further, the electron beam is easily deflected. Therefore, a structure for shielding or reducing an electric field generated by charging is required.

Therefore, in the present embodiment's the electronic component, the first side surface 2a of the first through hole 80 exposed in the vicinity of the first end 31 and the third end 35 is located outside of the first surface 30a and the third surface 34a, the first surface 30a is an inner side surface of the second portion 30, and the third surface 34a is an inner side surface of the fifth portion 34. Further, the second side surface 2b of the first through hole 80 exposed in the vicinity of the second end 33 and the fourth end 37 is located outside of the fifth surface 32a and the seventh surface 36a, the fifth surface 32a is an inner side surface of the third portion 32, and the seventh surface 36a is an inner side surface of the sixth portion 36. The seventh distance d7 between the second portion 30 and the first insulating film 40 in the vicinity of the second end 33 in the Y direction is longer than the second distance d2 between the second portion 30 and the third portion 32 in the Y direction. The eighth distance d8 between the third portion 32 and the first insulating film 40 in the vicinity of the first end 31 is longer than the second distance d2. The ninth distance d9 between the fifth portion 34 and the second insulating film 42 in the vicinity of the fourth end 37 in the Y direction is longer than the fifth distance d5 between the fifth portion 34 and the sixth portion 36 in the Y direction. The tenth distance d10 between the sixth portion 36 and the second insulating film 42 in the vicinity of the third end 35 is longer than the fifth distance d5 in the Y direction.

Thus, by arranging the first insulating film 40, the second insulating film 42, the first end 31, the third end 35, the second end 33 and the fourth end 37, it is possible to increase the distance between the electron beam passing area R and the side surface 40a1 or the side surface 40b1 of the first insulating film 40, or the side surface 42a1 or the side surface 42b2 of the second insulating film 42. Thus, even if the side surface 40a1 or the side surface 40b1 of the first insulating film 40 or the side surface 42a1 or the side surface 42b2 of the second insulating film 42 is charged, unexpected deflection of the charged particle beam can be suppressed.

The first distance d1 between the third portion 32 and the first side surface 2a of the first through hole 80 exposed in the vicinity of the first end 31 and the third end 35 in the Y direction is equal to or longer than the second distance d2 between the second portion 30 and the third portion 32. In addition, the third distance d3 between the second portion 30 and the second side surface 2b of the first through hole 80 exposed in the vicinity of the second end 33 and the fourth end 37 in the Y direction is equal to or longer than the second distance d2.

In addition, the fourth distance d4 between the sixth portion 36 and the first side surface 2a of the first through hole 80 exposed in the vicinity of the first end 31 and the third end 35 in the Y direction is equal to or longer than the fifth distance d5 between the fifth portion 34 and the sixth portion 36. In addition, the sixth distance d6 between the fifth portion 34 and the second side surface 2b of the first through hole 80 exposed in the vicinity of the second end 33 and the fourth end 37 in the Y direction is equal to or longer than the fifth distance d5 between the fifth portion 34 and the sixth portion

By arranging the first side surface 2a, the second side surface 2b, the first end 31, the third end 35, the second end 33, and the fourth end 37 in this manner, even if the first side surface 2a and the second side surface 2b are charged, the distance from the electron beam passing area R can be increased. Therefore, unexpected deflection of the charged particle beam can be suppressed. In this respect, the seventh distance d7 is preferably equal to or longer than the sum of the thickness t4 of the third portion 32 in the Y direction and the second distance d2. Further, the eighth distance d8 is preferably equal to or longer than the sum of the thickness t3 of the second portion 30 in the Y direction and the second distance d2. Further, the ninth distance d9 is preferably equal to or longer than the sum of the thickness t6 of the sixth portion 36 in the Y direction and the fifth distance d5. Further, the tenth distance d10 is preferably equal to or longer than the sum of the thickness t5 of the fifth portion 34 in the Y direction and the fifth distance d5.

According to the electronic component and the charged particle beam irradiation apparatus of the present embodiment, it is possible to provide the electronic component and the charged particle beam irradiation apparatus that can suppress unexpected deflection of the charged particle beam.

### Second Embodiment

The electronic component of the present embodiment differs from the electronic component of the first embodiment in that the first side surface 2a of the first substrate 2 in the vicinity of the first end 31 and the third end 35 protrudes more in the −Y direction than the first insulating film 40 and the second insulating film 42. In addition, the electronic component of the present embodiment differs from the electronic component of the first embodiment in that the second side surface 2b of the first substrate 2 in the vicinity of the second end 33 and the fourth end 37 protrudes more in the Y direction than the first insulating film 40 and the second insulating film 42. Descriptions of the contents overlapping with those of the first embodiment will be omitted.

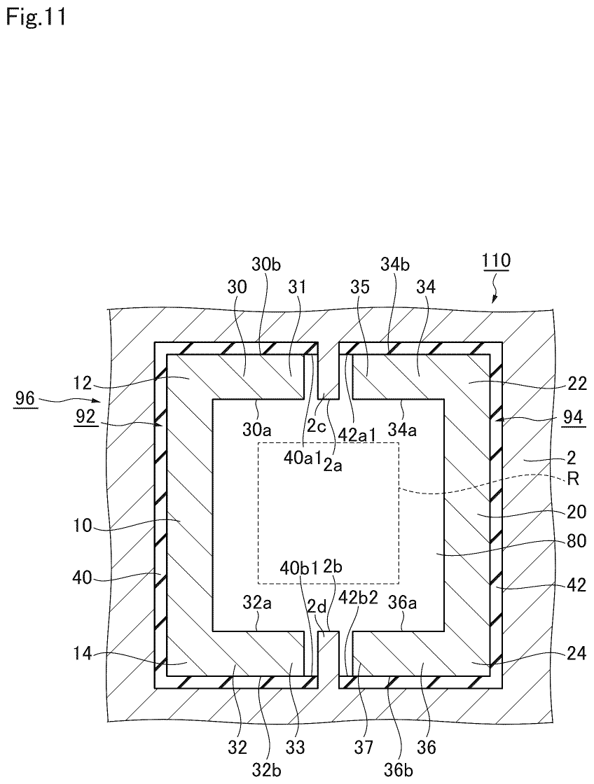

FIG. 11 is the schematic cross-sectional view of the electronic component 110 (structure A2) of the present embodiment. The first side surface 2a of the first substrate 2 in the vicinity of the first end 31 and the third end 35, by having the first protrusion 2c, protrudes more in the −Y direction than the first insulating film 40 and the second insulating film 42. In addition, the second side surface 2b of the first substrate 2 in the vicinity of the second end 33 and the fourth end 37, by having the second protrusion 2d, protrudes more in the Y direction than the first insulating film 40 and the second insulating film 42.

When the first substrate 2 is the Si substrate, the native oxide film (not shown) may be formed on the first side surface 2a or the second side surface 2b. Here, the thickness of the native oxide film of Si is very small, and is about several nm. Therefore, the capacitance of the native oxide film is larger than the capacitance of the first insulating film 40 or the second insulating film 42. On the other hand, the charges Q, the capacitance C, and the potential have a relationship of Q=CV. Therefore, when the amount of charge included by the native oxide film is equal to the amount of charge included by the first insulating film 40 or the second insulating film 42, the potential of the native oxide film is considered to be lower than the potential of the first insulating film 40 or the second insulating film 42. Therefore, even if the first side surface 2a and the second side surface 2b protrude more than the first insulating film 40 and the second insulating film 42, the effect on the deflecting of the electron beam is small.

According to the electronic component and the charged particle beam irradiation apparatus of the present embodiment, it is possible to provide the electronic component and the charged particle beam irradiation apparatus that can suppress unexpected deflection of the charged particle beam.

### Third Embodiment

The electronic component of the present embodiment differs from the electronic component of the first embodiment and the second embodiment in that a third insulating film 47a provided between the first end 31 and the third end 35, the third insulating film being connected to the first insulating film 40, a fourth insulating film 48a provided between the first end 31 and the third end 35, the fourth insulating film being connected to the second insulating film 42, wherein an eleventh distance between the third insulating film 47a and the third portion 32 is longer than a second distance in the first direction, and wherein a twelfth distance between the fourth insulating film 48a and the sixth portion 36 is longer than the fifth distance (second distance). Here, descriptions of the contents overlapping with those of the first and second embodiments will be omitted.

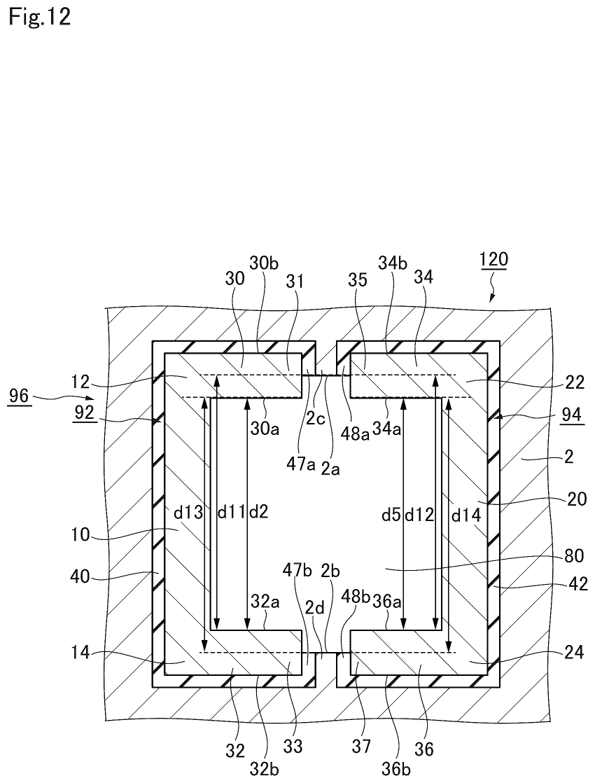

FIG. 12 is the schematic cross-sectional view of the main part of the electronic component 120 of the third embodiment. The electronic component 120 is structure A1_1u.

The third insulating film 47a is provided between the first end 31 and the third end 35, and is connected to the first insulating film 40. The third insulating film 47b is provided between the second end 33 and the fourth end 37, and is connected to the first insulating film 40.

The third insulating film 47a is provided between the first end 31 and the first protrusion 2c. The third insulating film 47b is provided between the second end 33 and the second protrusion 2d.

The fourth insulating film 48a is provided between the first end 31 and the third end 35, and is connected to the second insulating film 42. The fourth insulating film 48b is provided between the second end 33 and the fourth end 37, and is connected to the second insulating film 42.

The fourth insulating film 48a is provided between the third end 35 and the second protrusion 2d. The fourth insulating film 48b is provided between the fourth end 37 and the second protrusion 2d.

The third insulating film 47a, the third insulating film 47b, the fourth insulating film 48a and the fourth insulating film 48b include, for example, SiOx (Silicon Oxide).

The eleventh distance d11 between the third insulating film 47a and the third portion 32 in the Y direction is longer than the second distance d2 in the Y direction. The twelfth distance d12 between the fourth insulating film 48a and the sixth portion 36 in the Y direction is longer than the fifth distance d5 in the Y direction. The thirteenth distance d13 between the third insulating film 47b and the second portion 30 in the Y direction is longer than the second distance d2 in the Y direction. The fourteenth distance d14 between the fourth insulating film 48b and the fifth portion 34 in the Y direction is longer than the fifth distance d5 in the Y direction.

For example, the third insulating film 47a and the third insulating film 47b are formed simultaneously with the first insulating film 40. For example, the fourth insulating film 48a and the fourth insulating film 48b are formed simultaneously with the second insulating film 42.

According to the electronic component and the charged particle beam irradiation apparatus of the present embodiment, it is possible to provide the electronic component and the charged particle beam irradiation apparatus that can suppress unexpected deflection of the charged particle beam.

### Fourth Embodiment

The present embodiment's the electronic component differs from the electronic component of the first to third embodiments in that a portion of a second surface 30b of the second portion 30 provided on the opposite side of the first surface 30a is exposed, and a portion of a fourth surface 34b of the fifth portion 34 provided on the opposite side of the third surface 34a is exposed. Here, descriptions of the contents overlapping with those of the first to third embodiments will be omitted.

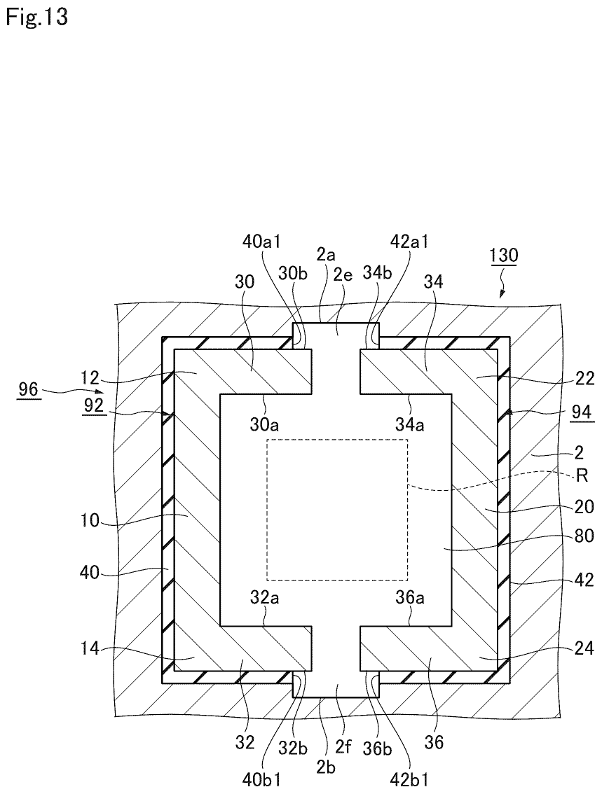

FIG. 13 is the schematic cross-sectional view of the electronic component 130 of the present embodiment. The electronic component 130 is structure C1.

The first side surface 2a of the first through hole 80 includes the first recess 2e. The first recess 2e is provided between the second surface 30b and the first substrate 2 in the Y direction, and between the fourth surface 34b and the first substrate 2 in the Y direction. Thus, a portion of the second surface 30b of the second portion 30 provided opposite to the first surface 30a facing the third portion 32 is exposed. Further, a portion of the fourth surface 34b of the fifth portion 34 provided opposite to the third surface 34a facing the sixth portion 36 is exposed.

The exposed side surface 40a1 of the first insulating film 40 is in contact with the second surface 30b. The exposed side surface 42a1 of the second insulating film 42 is in contact with the fourth surface 34b.

The second side surface 2b of the first through hole has the second recess 2f. The second recess 2f is provided over between the sixth surface 32b and the first substrate 2 in the Y direction, and between the eighth surface 36b and the first substrate 2 in the Y direction. Thus, a portion of the sixth surface 32b of the third portion 32 provided opposite to the fifth surface 32a facing the second portion 30 is exposed. Also, a portion of the eighth surface 36b of the sixth portion 36 provided opposite to the seventh surface 36a facing the fifth portion 34 is exposed.

The exposed side surface 40b1 of the first insulating film 40 is in contact with the sixth surface 32b. The exposed side surface 42b2 of the second insulating film 42 is in contact with the fourth surface 34b.

According to the electronic component 130 of the present embodiment, the second portion 30 is provided between the exposed side surface 40a1 of the first insulating film 40 and the electron beam passing area R by providing the first recess 2e. Therefore, the influence of the electric field applied to the electron beam passing region R by the electric potential applied to the second portion 30 can be made larger than the influence of the electric field applied to the electron beam passing region R by the side surface 40a1 electrostatic charge of the first insulating film 40. The same applies to the side surface 40b1 of the first insulating film 40, the side surface 42a1 of the second insulating film 42, and the side surface 42b2 of the second insulating film 42.

According to the electronic component and the charged particle beam irradiation apparatus of the present embodiment, it is possible to provide the electronic component and the charged particle beam irradiation apparatus that can suppress unexpected deflection of the charged particle beam.

### Fifth Embodiment

The present embodiment's the electronic component differs from the first end of the fourth embodiment the third end in that the first side surface 2a of the first substrate 2 in the vicinity of the first end 31 and the third end 35 includes a first protrusion 2c, and the second side surface 2b of the first substrate 2 in the vicinity of the second end 33 and the fourth end 37 includes a second protrusion 2d. Descriptions of the contents overlapping with those of the first to fourth embodiments will be omitted.

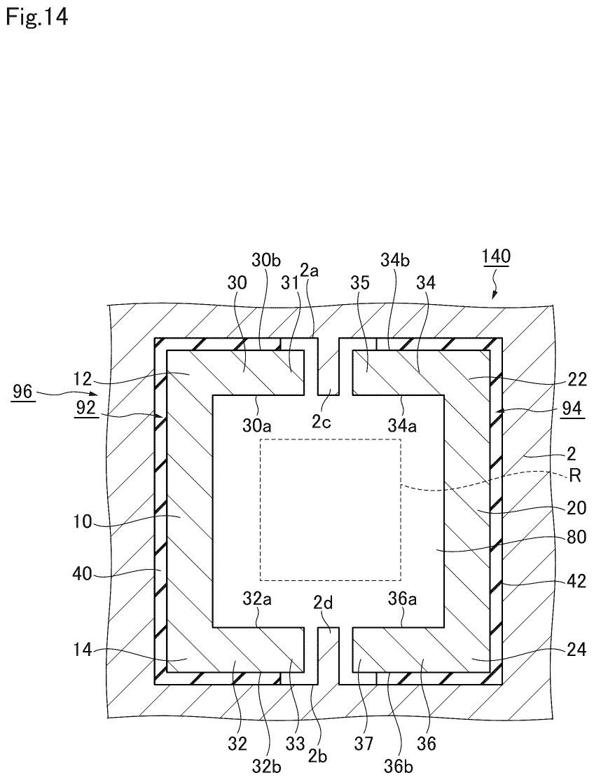

FIG. 14 is the schematic cross-sectional view of the electronic component 140 of the present embodiment. The electronic component 140 is structure C2.

According to the electronic component and the charged particle beam irradiation apparatus of the present embodiment, it is possible to provide the electronic component and the charged particle beam irradiation apparatus that can suppress unexpected deflection of the charged particle beam.

### Sixth Embodiment

The electronic component of the present embodiment is different from the electronic component of the fourth embodiment in that the electronic component further includes a fifth insulating film 49a provided in contact with the first side surface 2a, and a seventh electrode 38a provided in contact with the fifth insulating film 49a and spaced apart from the second portion 30 and the fifth portion 54. Descriptions of the contents overlapping with those of the first to fifth embodiments will be omitted.

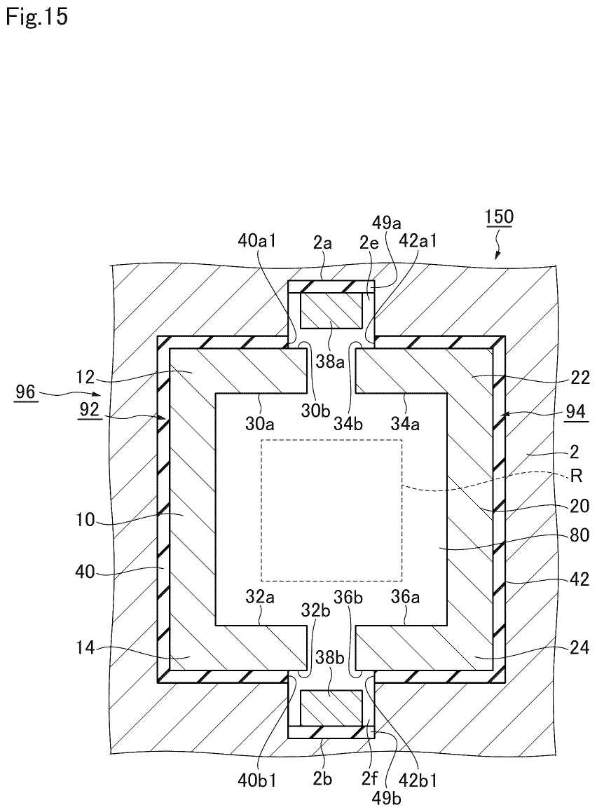

FIG. 15 is the schematic cross-sectional view of the electronic component 150 of the present embodiment. The electronic component 150 is structure D1.

The fifth insulating film 49a is provided in contact with the first side surface 2a. Note that the fifth insulating film 49a may be provided to be in indirect contact with the first side surface 2a by providing a native oxide film (not shown) between the fifth insulating film 49a and the first side surface 2a.

The seventh electrode 38a is in contact with the fifth insulating film 49a and is spaced apart from the second portion 30 and the fifth portion 34.

The sixth insulating film 49b is provided in contact with the second side surface 2b. Note that the sixth insulating film 49b may be provided to be in indirect contact with the second side surface 2b by providing a native oxide film (not shown) between the sixth insulating film 49b and the second side surface 2b.

The fifth insulating film 49a and the sixth insulating film 49b include, for example, silicon oxide (SiOx).

The eighth electrode 38b is in contact with the sixth insulating film 49b and is spaced apart from the third portion 32 and the sixth portion 36.

The seventh electrode 38a and the eighth electrode 38b include, for example, a metal nitride such as TiN (titanium nitride) or a metal such as W (tungsten).

The seventh electrode 38a and the eighth electrode 38b are grounded by, for example, the wiring (not shown). Note that other electric potentials may be applied to the seventh electrode 38a and the eighth electrode 38b.

According to the electronic component 150 of the present embodiment, an appropriate electric potential is applied to the seventh electrode 38a, such as by grounding the seventh electrode 38a and the eighth electrode 38b. This makes it possible to further reduce the effect of the electric field applied to the electron beam passing area R by the electrostatic charge of the side surface 40a1 of the first insulating film

According to the electronic component and the charged particle beam irradiation apparatus of the present embodiment, it is possible to provide the electronic component and the charged particle beam irradiation apparatus that can suppress unexpected deflection of the charged particle beam.

### Seventh Embodiment

The electronic component of the present embodiment differs from the second portion 30 of the first to sixth embodiments in that the second portion 30 includes a third protrusion 30c connected to the second surface 30b provided on the opposite side of the first surface 30a facing the third portion 32, and the fifth portion 34 includes a fourth protrusion 34c connected to the fourth surface 34b provided on the opposite side of the third surface 34a facing the sixth portion 36. Descriptions of the contents overlapping with those of the first to sixth embodiments will be omitted.

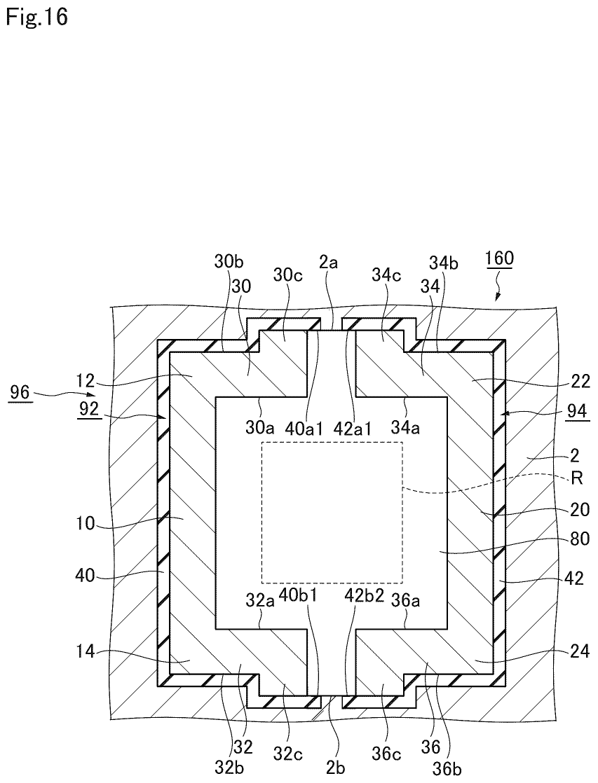

FIG. 16 is the schematic cross-sectional view of the electronic component 160 of the present embodiment. The electronic component 160 is structure B1.

The second portion 30 has the third protrusion 30c connected to the second surface 30b of the second portion 30, and the second surface 30b is provided opposite to the first surface 30a facing the third portion 32.

The fifth portion 34 has the fourth protrusion 34c connected to the fourth surface 34b of the fifth portion 34, and the fourth surface 34b is provided opposite to the third surface 34a facing the sixth portion 36.

The third portion 32 has the fifth protrusion 32c connected to the sixth surface 32b of the third portion 32, and the sixth surface 32b is provided opposite to the fifth surface 32a facing the second portion 30.

The sixth portion 36 has the sixth protrusion 36c connected to the eighth surface 36b of the sixth portion 36, and the eighth surface 36b is provided opposite to the seventh surface 36a facing the fifth portion 34.

The first insulating film 40 is provided in contact with the third protrusion 30c and the fifth protrusion 32c.

The second insulating film 42 is provided in contact with the fourth protrusion 34c and the sixth protrusion 36c.

According to the electronic component 160 of the present embodiment, the third protrusion 30c, the fourth protrusion 34c, the fifth protrusion 32c, and the sixth protrusion 36c can be provided to further increase the length between the electron beam passing area R and the side surface 42a1 or the side surface 42b2 of the first insulating film 40, or the side surface 40a1 or the side surface 40b1 of the second insulating film 42. Thus, even if the side surface 40a1 or the side surface 40b1 of the first insulating film 40, or the side surface 42a1 or the side surface 42b2 of the second insulating film 42 is charged, unexpected deflection of the charged particle beam can be further suppressed.

In addition, the distance between the first side surface 2a and the electron beam passing area R, and the distance between the second side surface 2b and the electron beam passing area R can be further increased. As a result, it is possible to further suppress unexpected deflection of the charged particle beam.

According to the electronic component and the charged particle beam irradiation apparatus of the present embodiment, it is possible to provide the electronic component and the charged particle beam irradiation apparatus that can suppress unexpected deflection of the charged particle beam.

### EXAMPLES

The electronic component according to the above embodiment was manufactured. In the electronic component 100, the first through hole 80 was a square having a diameter of 10 μm in the X direction and the Y direction. The electric potentials of the first substrate 2, the first portion 10, the fourth portion 20, the second portion 30, the third portion 32, the fifth portion 34 and the sixth portion 36 were set to 0V. A native oxide film having a thickness of about 1 nm was formed on the first side surface 2a and the second side surface 2b. The surface of the native oxide film was charged at a charge density of 10 μC per cm².

Further, in the electronic component 120 (structure A1_1u) of the third embodiment, the distance between the first surface 30a and the third surface 34a, and the side surface 40a1 of the first insulating film 40, the first side surface 2a of the first through hole 80, and the side surface 42a1 of the second insulating film 42, in the Y direction, was 1 μm. Further, in the electronic component 100 (structure A1_2u) of the first embodiment, the distance between the first surface 30a and the third surface 34a, and the side surface 40a1 of the first insulating film 40, the first side surface 2a of the first through hole 80, and the side surface 42a1 of the second insulating film 42, in the Y direction, was 2 μm.

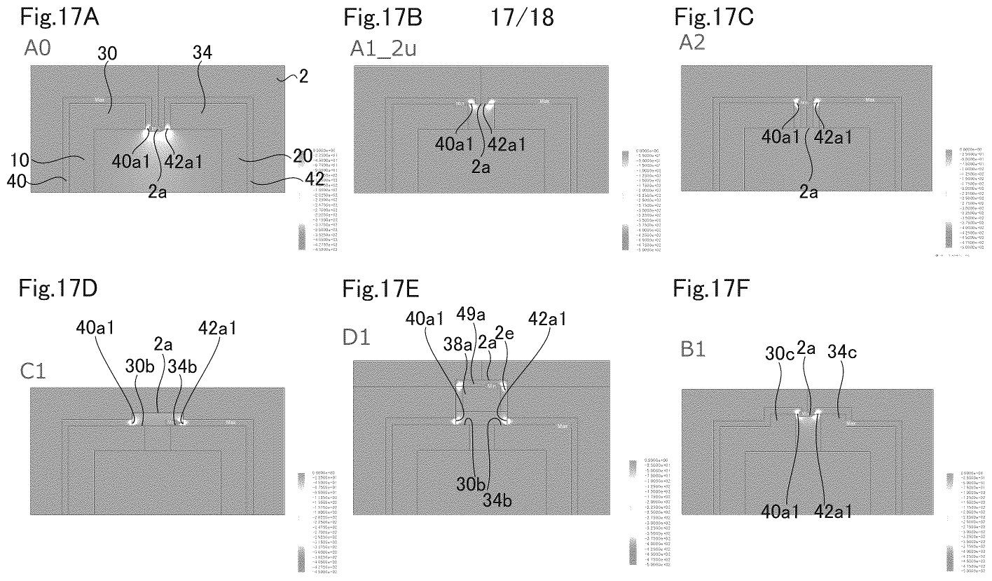

FIGS. 17A-F are the electric potential distribution of the electronic component of the embodiment. FIG. 17A is the electric potential distribution of the comparative electronic component 1000. FIG. 17B is the electric potential distribution of the electronic component 100 of the first embodiment. FIG. 17C is the electric potential distribution of the electronic component 110 of the second embodiment. FIG. 17D is the electric potential distribution of the electronic component 130 of the fourth embodiment. FIG. 17E is the electric potential distribution of the electronic component 150 of the sixth embodiment. FIG. 17F is the electric potential distribution of the electronic component 160 of the seventh embodiment.

In the electronic component shown in FIG. 17B to FIG. 17F, it can be confirmed that the region where the electric potential increases with charging is farther away from the electron beam passing region R as compared with the electronic component shown in FIG. 17A. A native oxide film was formed on the first side surface 2a and the second side surface 2b, but the film thickness was 1 nm and very thin. Since the capacitance is inversely proportional to the film thickness, the capacitances of the first side surface 2a and the second side surface 2b are much larger than the capacitances of the first insulating film 40 and the second insulating film 42 when comparing the capacitances when these surfaces are charged. Since the capacitance C is related to the charge Q and the electric potential V with Q=CV, the electric potential increase of the first side surface 2a and the second side surface 2b due to electrostatic charge becomes smaller compared to the electric potential increase of the first insulating film 40 and the second insulating film 42. Thus, it can be seen that the effects of the side surface 40a1 and the side surface 40b1 of the first insulating film 40, and the side surface 42a1 and the side surface 42b2 of the second insulating film 42 are longer.

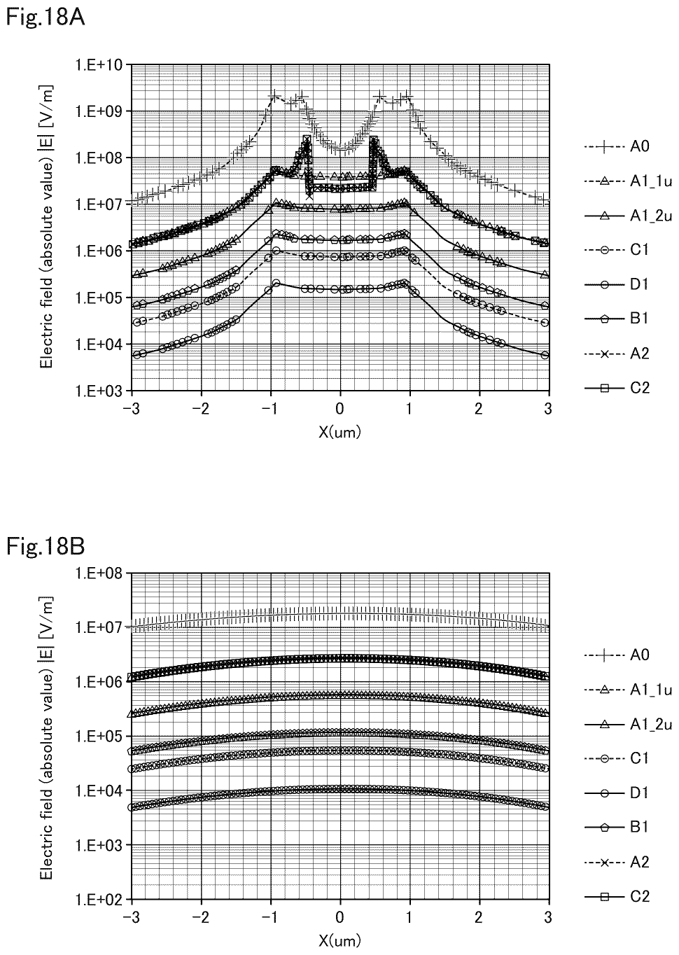

FIGS. 18A-B are graphs of the electric field of the electronic component of the embodiment. FIG. 18A is the electric potential distribution in the X direction in a plane parallel to the XZ plane passing through the first surface 30a and the third surface 34a. FIG. 18B is the electric potential distribution in the X direction in a plane parallel to the XZ plane spaced 2 μm from the first surface 30a and the third surface 34a in the −Y direction (the edge of the electron beam passing area R). In the electronic component of any embodiment, it can be seen that the electric field is lower than that in the electronic component of the comparative embodiment.

When comparing the deflecting angle of the electron beam in a plane parallel to the XZ plane passing through the first surface 30a and the third surface 34a, the deflecting angle of the electronic component 110 (structure A2) of the second embodiment is about an order of magnitude smaller than that of the electronic component of the comparative embodiment. In addition, the deflecting angle of the electronic component 140 (structure C2) of the fifth embodiment is about an order of magnitude smaller than that of the electronic component of the comparative embodiment. Furthermore, in the electric potential distribution in the X direction, the deflecting angles of the electronic component 120 (structure A1_1u) of the third embodiment and the electronic component 100 (structure A1_2u) of the first embodiment are reduced.

In the electronic component 160 (structure B1) of the seventh embodiment, the electronic component 130 (structure C1) of the fourth embodiment, and the electronic component 150 (structure D1) of the sixth embodiment, the deflecting angle is further reduced. The deflecting angle of the electronic component 150 (structure D1) of the sixth embodiment is about four orders of magnitude smaller than that of the electronic component (structure A0) of the comparative embodiment.

The charged particle beam irradiation apparatus including the multi charged particle beam irradiation apparatus includes the charged particle beam writing apparatus for writing a mask pattern on a mask blank using the charged particle beam including an electron beam, and the charged particle beam inspection apparatus for inspecting the mask pattern by detecting secondary electrons generated by irradiating the mask pattern with an electron beam.

The electronic component described in the above embodiments is applicable to the charged particle beam irradiation apparatus including the multi charged particle beam irradiation apparatus. In other words, the electronic component described in the above embodiment is applicable to the charged particle beam inspection apparatus including the multi charged particle beam inspection apparatus, in addition to the charged particle beam writing apparatus including the multi charged particle beam writing apparatus.

While certain embodiments and examples have been described, these embodiments and examples have been presented by way of example only, and are not intended to limit the scope of the inventions. These novel embodiments can be implemented in various other forms, and various omissions, replacements, and modifications can be made without departing from the gist of the invention. These embodiments and variations thereof fall within the scope and spirit of the invention, and fall within the scope of the invention described in the claims and equivalents thereof.

The above described embodiments can be summarized in the following technical solutions.

(Technological Proposal 1) An electronic component including:
a first substrate including
   a plurality of first through holes, each of a plurality of charged particle beams passes through each of the plurality of first through holes,
   a first substrate plane, and
   a second substrate plane provided on the opposite side of the first substrate plane;
a plurality of electrode pairs, each of the plurality of electrode pairs being provided in each of the plurality of first through holes, and each of the plurality of electrode pairs including
   a first electrode including
      a first portion,
      a second portion connected to the first portion, and the second portion including a first end, and
      a third portion connected to the first portion, and the third portion including a second end, and
   a second electrode spaced apart from the first electrode, the second electrode facing the first electrode, and the second electrode including
      a fourth portion facing the first portion,
      a fifth portion connected to the fourth portion, the fifth portion including a third end, and the third end facing the first end, and
      a sixth portion connected to the fourth portion, the sixth portion including a fourth end, and the fourth end facing the second end;
an insulating film, at least a part of the insulating film being provided between an inner side surface of each of the first through holes and an outer side surface of the first electrode and between the inner side surface of each of the first through holes and an outer side surface of the second electrode;
wherein a surface of the insulating film exposed from the first electrode and the second electrode in the vicinity of the first end and the third end is located outside of a first surface and a third surface, the first surface is an inner side surface of the second portion, and the third surface is an inner side surface of the fifth portion, and
wherein the surface of the insulating film exposed from the first electrode and the second electrode in the vicinity of the second end and the fourth end is located outside of a fifth surface and a seventh surface, the fifth surface is an inner side surface of the third portion, and the seventh surface is an inner side surface of the sixth portion.

(Technological Proposal 2) The electronic component according to Technological proposal 1,
wherein a first distance between a first side surface of the first through hole and the third portion is equal to or longer than a second distance between the second portion and the third portion, and the first side surface is exposed in the vicinity of the first end and the third end,
wherein a third distance between a second side surface of the first through hole and the second portion is equal to or longer than the second distance, and the second side surface is exposed in the vicinity of the second end and the fourth end,
wherein a seventh distance between the second portion and the insulating film in the vicinity of the second end is longer than the second distance,
wherein an eighth distance between the third portion and the insulating film in the vicinity of the first end is longer than the second distance,
wherein a ninth distance between the fifth portion and the insulating film in the vicinity of the fourth end is longer than the fifth distance between the fifth portion and the sixth portion, and
wherein a tenth distance between the sixth portion and the insulating film in the vicinity of the third end is longer than the fifth distance.

(Technological Proposal 3) The electronic component according to Technological proposal 2,
wherein a fourth distance between the first side surface and the sixth portion is equal to or longer than the fifth distance, and
wherein a sixth distance between the second side surface and the fifth portion is equal to or longer than the fifth distance.

(Technological Proposal 4) The electronic component according to Technological proposal 1,
wherein a first side surface of the first through hole protrudes inward from the insulating film, and the first side surface is exposed in the vicinity of the first end and the third end, and
wherein a second side surface of the first through hole protrudes inward from the insulating film, and the second side surface is exposed in the vicinity of the second end and the fourth end.

(Technological Proposal 5) The electronic component according to Technological proposal 1,
wherein the insulating film further includes
   a third insulating film provided in the vicinity of the first end and being provided between the first end and the third end, and
   a fourth insulating film provided in the vicinity of the third end and being provided between the first end and the third end, and
wherein an eleventh distance between the third insulating film and the third portion is longer than a second distance between the second portion and the third portion, and
wherein a twelfth distance between the fourth insulating film and the sixth portion is longer than the second distance.

(Technological Proposal 6) The electronic component according to Technological proposal 1,
wherein a portion of a second surface of the second portion provided on the opposite side of the first surface is exposed, and
wherein a portion of a fourth surface of the fifth portion provided on the opposite side of the third surface is exposed.

(Technological Proposal 7) The electronic component according to Technological proposal 6,
wherein the insulating film further includes a fifth insulating film provided in contact with a first side surface of the first through hole, and the first side surface is exposed in the vicinity of the first end and the third end,
and the electronic component further comprising:
a seventh electrode provided in contact with the fifth insulating film and spaced apart from the second portion and the fifth portion.

(Technological Proposal 8) The electronic component according to Technological proposal 1,
wherein the second portion includes a third protrusion connected to a second surface provided on the opposite side of the first surface, and
wherein the fifth portion includes a fourth protrusion connected to a fourth surface provided on the opposite side of the third surface.

(Technological Proposal 9) The electronic component according to Technological proposal 2,
wherein the seventh distance is equal to or longer than a sum of the second distance and a film thickness of the third portion,
wherein the eighth distance is equal to or longer than a sum of the second distance and a film thickness of the second portion,
wherein the ninth distance is equal to or longer than a sum of the fifth distance and a film thickness of the sixth portion, and
wherein the tenth distance is equal to or longer than a sum of the fifth distance and a film thickness the fifth portion.

(Technological Proposal 10) The electronic component according to Technological proposal 1,
wherein a first side surface of the first through hole includes a first protrusion protruding inward from the first side surface, and the first side surface is exposed in the vicinity of the first end and the third end,
wherein a second side surface of the first through hole includes a second protrusion protruding inward from the second side surface, and the second side surface is exposed in the vicinity of the second end and the fourth end,
wherein a distance between the insulating film in the vicinity of the second portion and the insulating film in the vicinity of the fifth portion is longer than a length of the first protrusion in the direction from the second portion to the fifth portion, and
wherein a distance between the insulating film in the vicinity of the third portion and the insulating film in the vicinity of the sixth portion is longer than a length of the second protrusion in the direction from the third portion to the sixth portion.

(Technological Proposal 11) The electronic component according to Technological proposal 1,
wherein the insulating film includes silicon oxide.

(Technological Proposal 12) The electronic component according to Technological proposal 1, further comprising:
a plurality of first junction electrodes provided on the first substrate plane, each of the plurality of first junction electrodes being electrically connected to each of the plurality of first electrodes;
a plurality of second junction electrodes provided on the first substrate plane, each of the plurality of second junction electrodes being electrically connected to each of the plurality of second electrodes;
a second substrate including a plurality of second through holes and a third substrate surface facing the first substrate plane;
a plurality of third junction electrodes provided on the third substrate plane, each of the plurality of third junction electrodes being electrically connected to each of the plurality of first junction electrodes; and
a plurality of fourth junction electrodes provided on the third substrate plane, each of the plurality of fourth junction electrodes being electrically connected to each of the plurality of second junction electrodes.

(Technological Proposal 13) The electronic component according to Technological proposal 12,
wherein the plurality of first junction electrodes, the plurality of second junction electrodes, the plurality of third junction electrodes, and the plurality of fourth junction electrodes include Au (gold).

(Technological Proposal 14) A charged particle beam irradiation apparatus comprising the electronic component according to Technological proposal 1.

What is claimed is:

1. An electronic component comprising:
a first substrate including
a plurality of first through holes, each of a plurality of charged particle beams passes through each of the plurality of first through holes,
a first substrate plane, and
a second substrate plane provided on the opposite side of the first substrate plane;
a plurality of electrode pairs, each of the plurality of electrode pairs being provided in each of the plurality of first through holes, and each of the plurality of electrode pairs including
a first electrode including
a first portion,
a second portion connected to the first portion, and the second portion including a first end, and
a third portion connected to the first portion, and the third portion including a second end, and
a second electrode spaced apart from the first electrode, the second electrode facing the first electrode, and the second electrode including
a fourth portion facing the first portion,
a fifth portion connected to the fourth portion, the fifth portion including a third end, and the third end facing the first end, and
a sixth portion connected to the fourth portion, the sixth portion including a fourth end, and the fourth end facing the second end;
an insulating film, at least a part of the insulating film being provided between an inner side surface of each of the first through holes and an outer side surface of the first electrode and between the inner side surface of each of the first through holes and an outer side surface of the second electrode;
wherein a surface of the insulating film exposed from the first electrode and the second electrode in the vicinity of the first end and the third end is located outside of a first surface and a third surface, the first surface is an inner surface of the second portion, and the third surface is an inner surface of the fifth portion, and
wherein the surface of the insulating film exposed from the first electrode and the second electrode in the vicinity of the second end and the fourth end is located outside of a fifth surface and a seventh surface, the fifth surface is an inner surface of the third portion, and the seventh surface is an inner surface of the sixth portion.

2. The electronic component according to claim 1,
wherein a first distance between a first side surface of the first through hole and the third portion is equal to or longer than a second distance between the second portion and the third portion, and the first side surface is exposed in the vicinity of the first end and the third end,
wherein a third distance between a second side surface of the first through hole and the second portion is equal to or longer than the second distance, and the second side surface is exposed in the vicinity of the second end and the fourth end,
wherein a seventh distance between the second portion and the insulating film in the vicinity of the second end is longer than the second distance,
wherein an eighth distance between the third portion and the insulating film in the vicinity of the first end is longer than the second distance,
wherein a ninth distance between the fifth portion and the insulating film in the vicinity of the fourth end is longer than the fifth distance between the fifth portion and the sixth portion, and
wherein a tenth distance between the sixth portion and the insulating film in the vicinity of the third end is longer than the fifth distance.

3. The electronic component according to claim 2,
wherein a fourth distance between the first side surface and the sixth portion is equal to or longer than the fifth distance, and
wherein a sixth distance between the second side surface and the fifth portion is equal to or longer than the fifth distance.

4. The electronic component according to claim 1,
wherein a first side surface of the first through hole protrudes inward from the insulating film, and the first side surface is exposed in the vicinity of the first end and the third end, and
wherein a second side surface of the first through hole protrudes inward from the insulating film, and the second side surface is exposed in the vicinity of the second end and the fourth end.

5. The electronic component according to claim 1,
wherein the insulating film further includes
a third insulating film provided in the vicinity of the first end and being provided between the first end and the third end, and
a fourth insulating film provided in the vicinity of the third end and being provided between the first end and the third end, and
wherein an eleventh distance between the third insulating film and the third portion is longer than a second distance between the second portion and the third portion, and
wherein a twelfth distance between the fourth insulating film and the sixth portion is longer than the second distance.

6. The electronic component according to claim 1,
wherein a portion of a second surface of the second portion provided on the opposite side of the first surface is exposed, and
wherein a portion of a fourth surface of the fifth portion provided on the opposite side of the third surface is exposed.

7. The electronic component according to claim 6,
wherein the insulating film further includes a fifth insulating film provided in contact with a first side surface of the first through hole, and the first side surface is exposed in the vicinity of the first end and the third end,
and the electronic component further comprising:
a seventh electrode provided in contact with the fifth insulating film and spaced apart from the second portion and the fifth portion.

8. The electronic component according to claim 1,
wherein the second portion includes a third protrusion connected to a second surface provided on the opposite side of the first surface, and
wherein the fifth portion includes a fourth protrusion connected to a fourth surface provided on the opposite side of the third surface.

9. The electronic component according to claim 2,
wherein the seventh distance is equal to or longer than a sum of the second distance and a film thickness of the third portion,
wherein the eighth distance is equal to or longer than a sum of the second distance and a film thickness of the second portion,
wherein the ninth distance is equal to or longer than a sum of the fifth distance and a film thickness of the sixth portion, and
wherein the tenth distance is equal to or longer than a sum of the fifth distance and a film thickness the fifth portion.

10. The electronic component according to claim 1,
wherein a first side surface of the first through hole includes a first protrusion protruding inward from the first side surface, and the first side surface is exposed in the vicinity of the first end and the third end,
wherein a second side surface of the first through hole includes a second protrusion protruding inward from the second side surface, and the second side surface is exposed in the vicinity of the second end and the fourth end,
wherein a distance between the insulating film in the vicinity of the second portion and the insulating film in the vicinity of the fifth portion is longer than a length of the first protrusion in the direction from the second portion to the fifth portion, and
wherein a distance between the insulating film in the vicinity of the third portion and the insulating film in the vicinity of the sixth portion is longer than a length of the second protrusion in the direction from the third portion to the sixth portion.

11. The electronic component according to claim 1,
wherein the insulating film includes silicon oxide.

12. The electronic component according to claim 1, further comprising:
a plurality of first junction electrodes provided on the first substrate plane, each of the plurality of first junction electrodes being electrically connected to each of the plurality of first electrodes;
a plurality of second junction electrodes provided on the first substrate plane, each of the plurality of second junction electrodes being electrically connected to each of the plurality of second electrodes;
a second substrate including a plurality of second through holes and a third substrate surface facing the first substrate plane;
a plurality of third junction electrodes provided on the third substrate plane, each of the plurality of third junction electrodes being electrically connected to each of the plurality of first junction electrodes; and
a plurality of fourth junction electrodes provided on the third substrate plane, each of the plurality of fourth junction electrodes being electrically connected to each of the plurality of second junction electrodes.

13. The electronic component according to claim 12,
wherein the plurality of first junction electrodes, the plurality of second junction electrodes, the plurality of third junction electrodes, and the plurality of fourth junction electrodes include Au (gold).

14. A charged particle beam irradiation apparatus comprising the electronic component according to claim 1.
